(19) United States
(12) Patent Application Publication
(10) Pub. No.: US 2010/0159286 A1
(43) Pub. Date: Jun. 24, 2010

(54) PERPENDICULAR MAGNETIC RECORDING MEDIUM

(75) Inventors: Amarendra Kumar SINGH, Singapore (SG); Daizo Endo, Singapore (SG)

Correspondence Address: SUGHRUE MION, PLLC, 2100 PENNSYLVANIA AVENUE, N.W., SUITE 800, WASHINGTON, DC, 20037, US

(73) Assignee: Showa Denko HD Singapore Pte Ltd., Singapore (SG)

(21) Appl. No.: 12/639,724

(22) Filed: Dec. 16, 2009

(30) Foreign Application Priority Data
Dec. 19, 2008 (SG) 200809508-5

(51) Int. Cl. G11B 5/706; B05D 5/12; C23C 14/34

(52) U.S. Cl. 428/846; 427/128; 204/192.15

(57) ABSTRACT

Disclosed is a perpendicular magnetic recording medium on a substrate. The perpendicular magnetic recording medium has a recording layer. The recording layer includes a first granular recording layer and a second granular recording layer. There may be an exchange layer between the first granular recording layer and the second granular recording layer. Additionally or alternatively, the ratio of saturation magnetization of the first granular recording layer and the second granular recording layer may be greater than 1 and/or the first granular recording layer may have a relatively high magnetic anisotropy compared to the second granular recording layer magnetic anisotropy. A forming method is also disclosed.

### TECHNICAL FIELD

This invention relates to a perpendicular magnetic recording medium and refers particularly, though not exclusively, to a perpendicular magnetic recording medium having an exchange layer to provide improved thermal decay and recording performance. The invention has particular utility in high to ultra-high areal recording density media, such as, for example, hard disks utilizing granular perpendicular-type magnetic recording layers.

### BACKGROUND

It is well known that magnetic recording media are widely used in various applications, particularly in the computer industry. To increase the capacity of magnetic disk drives, efforts have been made to further improve the recording density, i.e. the bit density of the magnetic media. In order to achieve a magnetic recording medium, the bits are formed by a magnetic field in a direction that is perpendicular to the plane of the perpendicular magnetic recording medium, and that has a perpendicular magnetizing anisotropy.

In order to fabricate a perpendicular recording medium having a high signal-to-noise ratio (SNR), it is important to have a recording medium with small grains, uniform distribution of grain size, and uniform exchange coupling between the grains. A smaller magnitude of exchange coupling between the grains result in better switching of magnetic grains and a reduction in cross-track correlation length and media noise. However, very small (nearly zero) exchange coupling between magnetic particles or grains results a very low squareness-sheared M-H hysteresis loop, a broad switching field distribution, decreased resistance to self-demagnetization and thermal decay, and low nucleation fields. Non-uniform exchange coupling results in other magnetic particles or grains acting independently, and in clusters, resulting in a broad distribution of grain size and anisotropy field. This non-uniform exchange coupling between the grains (Hn distribution) becomes severe with increases in temperature. This can result in increased thermal decay at higher temperatures.

A perpendicular recording medium with uniform exchange interaction between grains and less decay of the Hn (dHn/dT) is needed in order to maintain the performance of perpendicular recording medium in drives with variations in operating temperature.

Exchange coupling between the grains is controlled by the formation of non-magnetic materials at the grain boundaries. The non-magnetic materials at the grain boundaries are formed during the sputter deposition of cobalt (Co), platinum (Pt), an oxide with additives of chromium, boron, zirconium, tungsten, titanium, tantalum and ruthenium (Cr, B, Zr, W, Ti, Ta and Ru respectively). However, the concentration of the Co atoms varies between the centre of the magnetic grains and the grain boundaries due to the formation of a non-magnetic phase inside the Co grains. Therefore, the exchange coupling between grains is normally controlled by process parameters, such as, for example, the content of Cr, B or Zr, or oxide of one or more of them, in the sputter targets. Another way to control the exchange coupling between the grains is by reactive sputter of the targets in a sputter gas containing oxygen (O₂).

However, this process causes the exchange coupling between the grains to be extremely sensitive. As a result, it is very difficult to maintain uniform and sufficient exchange coupling between grains. With increases in temperature, it may result in an enhanced, non-uniform exchange between the grains. Therefore, the Hn decay with temperature (dHn/dT) is increased. This results in increased thermal decay of the perpendicular recording medium.

It would be of advantage to have a perpendicular recording medium with a recording layer having a significantly lower decay of Hn (dHn/dT) and Hc (dHc/dT) with increases in temperature, and therefore a lower thermal decay of the perpendicular recording medium. It would be of further advantage to do so with a higher signal to noise ratio.

### SUMMARY

According to an exemplary aspect there is provided a perpendicular magnetic recording medium on a substrate. The perpendicular magnetic recording medium has a recording layer. The recording layer includes a first granular recording layer and a second granular recording layer. The ratio of saturation magnetization of the first granular recording layer and the second granular recording layer is greater than 1.

According to another exemplary aspect there is provided a perpendicular magnetic recording medium on a substrate. The perpendicular magnetic recording medium has a recording layer. The recording layer includes a first granular recording layer and a second granular recording layer. The first granular recording layer has a relatively high magnetic anisotropy compared to the second granular recording layer magnetic anisotropy.

For the second aspect, the ratio of saturation magnetization of the first granular recording layer and the second granular recording layer may be greater than 1. For the first aspects, the first granular recording layer may have a relatively high magnetic anisotropy compared to the second granular recording layer magnetic anisotropy.

For the both aspects, the recording layer may further comprise an exchange layer between the first granular recording layer and the second granular recording layer. The exchange layer may comprise CoCr. The Cr content may be in the range of 20 to 60 at %. The exchange layer may further comprise at least one additive selected from the group consisting of: TiO₂, Cr₂O₃, SiO₂, ZrO₂, B₂O₃, Nb₂O₅, MgO, Al₂O₃, Ta₂O₅, HfO₂, Y₂O₂, V₂O₅ and WO₃. The at least one additive may be in the range 0 to 20 at %. The exchange layer may have a thickness in the range 0 to 10 A. The perpendicular magnetic recording medium on a substrate may further comprise a soft underlayer on the substrate, and an isolation layer on the soft underlayer, the recording layer being on the isolation layer; and an upper recording layer on the second granular recording layer.

According to a final exemplary aspect there is provided a method for forming a perpendicular magnetic recording medium on a substrate, the method comprising forming a first granular recording layer, forming an exchange layer on the first granular recording layer, and forming a second granular recording layer on the exchange layer. The ratio of saturation magnetization of the first granular recording layer and the second granular recording layer may be greater than 1 and/or the first granular recording layer may have a relatively high magnetic anisotropy compared to the second granular recording layer magnetic anisotropy.

Before the first granular recording layer is formed, a soft underlayer may be formed on the substrate. An isolation layer may also be formed on the soft underlayer. The first granular recording layer may be formed on the isolation layer. Forming the soft underlayer may comprise forming a first soft underlayer on the substrate, forming a layer of ruthenium on the first soft underlayer, and forming a second soft underlayer on the layer of ruthenium. Forming the isolation layer may comprise forming an orientation control layer on the second soft underlayer and forming an intermediate layer on the orientation control layer. The method may further comprise forming an upper recording layer on the second granular recording layer, forming a protective layer on the upper recording layer, and forming a lubricant layer on the protective layer. The first granular layer, the exchange layer and the second granular layer may be formed by DC magnetron sputtering.

### BRIEF DESCRIPTION OF THE DRAWINGS

In order that the invention may be fully understood and readily put into practical effect there shall now be described by way of non-limitative example only exemplary embodiments, the description being with reference to the accompanying illustrative drawings.

In the drawings:

FIG. 1 is a schematic illustration (not to scale) of an exemplary embodiment of a perpendicular magnetic recording system with read-write head and perpendicular recording medium;

FIG. 2 is a schematic view of the structure (not to scale) of an exemplary perpendicular recording of FIG. 1;

FIG. 3 is a graph illustrating variations of dHn/dT, dHc/dT and the signal to noise ratio (SNR) of the exemplary perpendicular recording medium of FIG. 2; and

FIG. 4 is a flow chart of an exemplary method of fabrication.

### DETAILED DESCRIPTION OF THE EXEMPLARY EMBODIMENTS

The exemplary embodiments are directed to a perpendicular magnetic recording medium for application in magnetic recording systems.

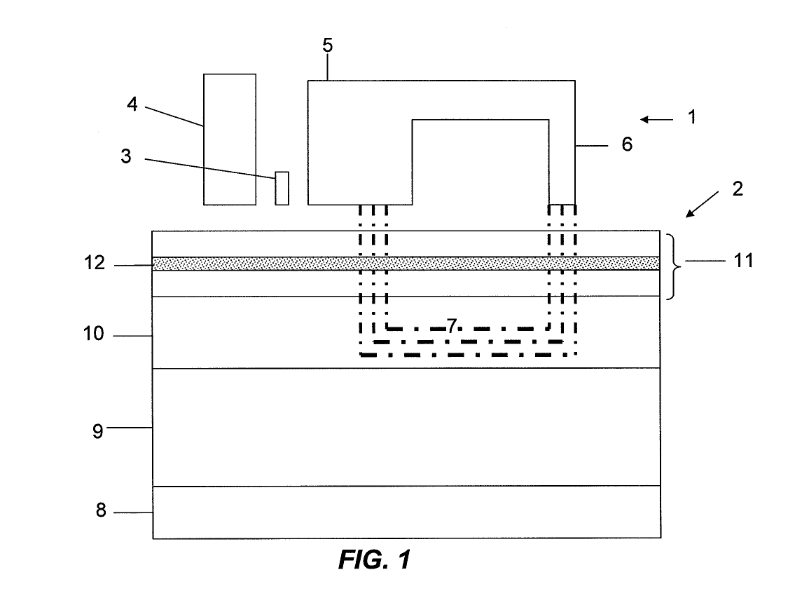

As shown in FIG. 1, an exemplary perpendicular recording system has magnetic recording head 1 and a perpendicular recording medium 2. The magnetic recording head 1 has a magnetic recording reader consisting of a magnetoresistive sensor 3 flanked by shields 4 and 5. The magnetic recording head 1 also has a write pole 6 and return pole 5. During a writing operation, write flux travels from write pole 6 through path 7 and returns to the return pole 5. The perpendicular recording medium 2 comprises a substrate 8, soft magnetic under layer (SUL) 9, isolation layer 10, and a recording layer 11 that includes an exchange layer 12.

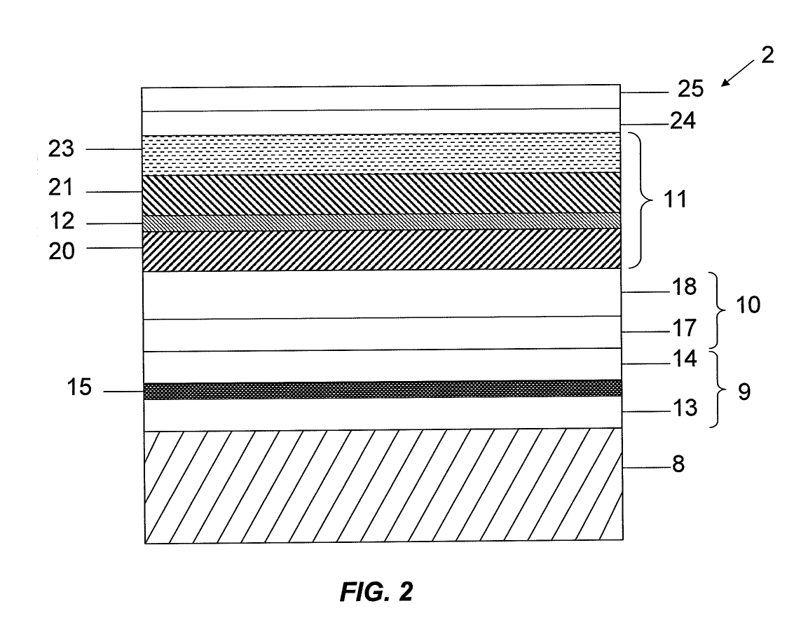

An exemplary schematic view (not to scale) of the structure of the perpendicular recording medium of FIG. 1 is shown in FIG. 2. The perpendicular recording medium 2 has a substrate 8. On the substrate 8 is deposited the soft under layer 9 having a first soft under layer 13 and second soft under layer 14 with a layer of ruthenium (Ru) 15 between the first and second soft under layers 13, 14.

The substrate 8 may be made of:
(i) a metallic material, such as, for example, aluminum or an aluminum alloy; or
(ii) a non-metallic material, such as, for example, glass, silicon or silicon carbide.

The average surface roughness of the substrate 8 is preferably not greater than 0.3 nm, and more preferably is not less than 0.2 nm. Furthermore, microwaviness is preferably not greater than 0.3 nm, and more preferably is not greater than 0.25 nm.

The material of the first and second soft under layers 13, 14 may be en alloy of Co and Fe with the Co:Fe in the ratio of 60:40 to 70:30 [Co and Fe contents] and with one or more additives from the group: Ta, Nb, Zr, Si, B, C, Al and C. The additive is preferably in the range 3 to 10 at %. It is preferable for soft underlayers 13, 14 to have an amorphous crystal structure. The advantage of having an amorphous crystal structure is that it helps the lattice to uniformly settle on the surface of the substrate 8 and therefore results in better uniformity of grains in the perpendicular medium structure. Furthermore, an amorphous soft under layer 13, 14 does not disturb the crystal orientation of the orientation control layer 17.

The coercivity of the soft under layer 9 is preferably in the range 5 Oe to 10 Oe. It is preferred that the saturation magnetization of soft underlayer 9 is in the range 0.6 T to 1.5 T. Each layer of the soft underlayer 9 may be formed by a sputtering process and, at the time of formation, it is preferred that a magnetic field is applied in the radial direction.

The Ru film 15 between the first and second soft underlayer 13, 14 provides an anti-ferromagnetic coupling between first and second underlayers 13, 14. This assists in suppressing DC noise generated during the read-write process. The soft underlayer 9 may help to minimize WATER (Wide Area Track Eraser) and ATI (Adjacent Track Interference) effects in the perpendicular recording medium. The soft underlayer 9 may assist in controlling the crystal orientation of the perpendicular recording medium.

The isolation layer 10 has an orientation control layer 17 formed on the second soft under layer 14, and an intermediate layer 18 formed on the orientation control layer 17.

Orientation control layer 17 is preferably of a Ni-alloy, Pt, Ta, or Pd-alloy. It is preferred that the thickness of orientation control layer 17 is not less than 1 nm and more preferably is not more than 15 nm. A thinner orientation control layer 17 may not be able to provide improved crystal growth and orientation of the grains in the recording layer 11. A thick orientation control layer 17 may result in an increase in the head-to-soft underlayer spacing and therefore may decrease the writibility, and the resolution of the reproductive signal.

The recording layer 11 is formed on the intermediate layer 18. The recording layer 11 includes a first granular recording layer 20 and a second granular recording layer 21 with exchange layer 12 between the first and second granular recording layers 20, 21. An upper recording layer 23, protective layer 24, and lubricant layer 25 are subsequently formed on the second granular recording layer 21.

The thickness of the isolation layer 10 is preferably not less than 10 nm and more preferably is not more than 30 nm. The intermediate layer 18 is preferably of Ru or an Ru-alloy. Another alloy may also be used for the intermediate layer 18 in order to decrease the grain size of the recording layer. The intermediate layer 18 helps to control the orientation of grains of the recording layer 11. It may also provide improved segregation of grains in the recording layer 11.

The recording layer 11 is formed on the intermediate layer 18. The recording layer 11 includes a first granular recording layer 20 and a second granular recording layer 21 with exchange layer 12 between the first and second granular recording layers 20, 21. An upper recording layer 23, protective layer 24, and lubricant layer 25 are subsequently formed on the second granular recording layer 21.

The recording layer 11 is formed by first and second granular recording layers 20, 21 with the exchange layer 12 between the first and second granular recording layers 20, 21. Magnetic anisotropy of the first granular recording layer 20 may be higher than that of the second granular recording layer 21.

The first granular recording layer 20 may be of a relatively high magnetic anisotropic material compared to the material of the second granular recording layer 21. Furthermore, the ratio of saturation magnetization (M1/M2) of the first (M1) and second (M2) granular recording layers 20, 21 is preferably greater than 1 (M1/M2>1). The exchange layer 12 may comprise CoCr with the Cr content preferably being in the range of 20 to 50 at %; and an additive of one or more of TiO₂, Cr₂O₃, SiO₂, and WO₃ in the range 0 to 20 at %. The exchange layer 12 may have a thickness in the range 0 to 6 A. The recording layer 11 also has an upper recording layer 23 formed on the second granular recording layer 21. The thickness of recording layer 11 is preferably between 10 to 20 nm. This is particularly so to maintain the signal output, SNR and overwrite characteristics.

The upper recording layer 23 may be one or more of: a granular recording layer, an exchange break layer, and a continuous layer. Preferably the upper recording layer 23 consists of Co, Pt and an oxide, with the easy axis orientation being perpendicular to the film normal. It preferably has additives of one or more of: Cr, B, Zr, W, Ti, Ta and Ru for further improvement in the SNR.

The protective layer 24 may include a material containing C, Ru, or SiO2. Its primary function is to prevent the damage to the recording medium surface, and to prevent corrosion of the perpendicular recording medium. The thickness of the protective layer 24 is preferably not lower than 1 nm, and more preferably is not greater than 5 nm.

Lubricant layer 25 may consist of one or more of: perfluoropolyether, a fluorinated alcohol, and fluorinated carboxylic acid.

All the layers of the perpendicular recording medium described above may be formed by DC magnetron sputtering except the protective layer 24. The protective layer 24 may be formed by chemical vapour deposition. The vacuum chamber may be evacuated to vacuum level of 10⁻⁵ or less.

In an example, first and second granular recording layers 20, 21 with different compositions and,
(a) with exchange layer (with EL), and
(b) without exchange layer (without EL) have been made. The magnetic anisotropy of the second layer 21 varied from the lower surface (on the exchange layer 12) to its upper surface.

Hysteresis loops were recorded at different temperature in the range 25° C. to 170° C. By recording the hysteresis loops at different temperatures, the thermal decay of Hc and Hn were able to be estimated. The recording performance was determined by use of a read/write analyzer and a spin-stand. A magnetic head using a single magnetic pole for writing, and a TMR element in the reproducing section, was used for the evaluation of the recording characteristics. A recording density of 1250 kfci was used. Thermal decay of Hc, Hn (dHc/dT, dHn/dT) and the signal to noise ratio (SNR) are listed in Table 1.

TABLE 1

| | Recording | | | MF |
|---|---|---|---|---|
| Specimen | Layer | dHn/dT | dHc/dT | SNR (dB) |
| Example-1 | With EL | −14.57 | −12.28 | 16.54 |
| Comparative Example-1 | Without EL | −19.68 | −15.29 | 16.27 |
| Example-2 | With EL | −18.07 | −13.29 | 16.70 |
| Comparative Example 2 | Without EL | −20.16 | −16.35 | 16.38 |
| Example 3 | With EL | −18.60 | −15.10 | 16.2 |
| Comparative Example 3 | Without EL | −21.31 | −17.69 | 15.8 |

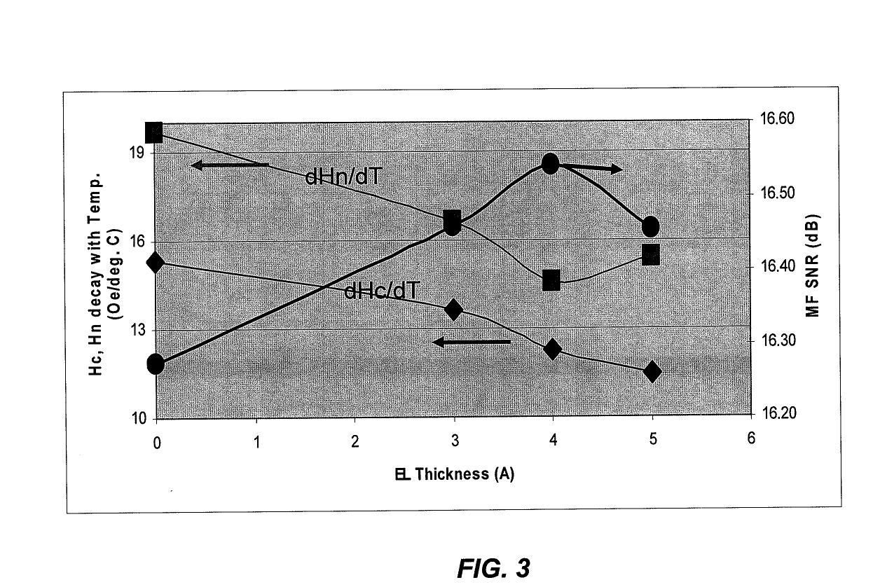

FIG. 3 shows a typical variation of thermal decay of Hc, Hn (dHc/dT, dHn/dT) and signal to noise ratio (SNR) with an exchange layer 12. The exchange layer 12 results in an improved decay rate of Hc and Hn with temperature (dHc/dT, dHn/dT), and an improved signal to noise ratio. The exchange layer 12 helps to control inter-granular exchange in the first and second granular recording layers 20, 21. This also assists in the lower decay of Hn at higher temperatures (dHn/dT).

Furthermore, the exchange layer 12 together with the second granular recording layer 21 helps to switch the higher magnetic anisotropy first granular recording layer 20 during the writing process. This results in better ROW and switching field distribution, and therefore a higher signal to noise ratio.

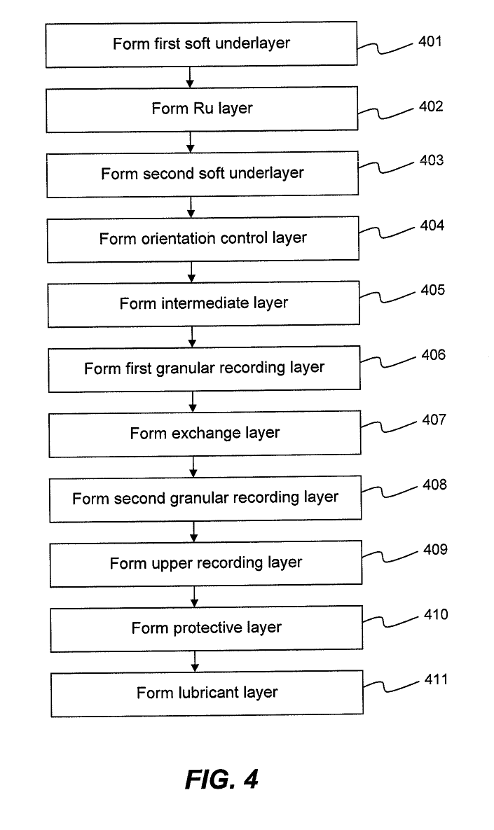

To refer to FIG. 4, the process is to first form the first soft underlayer 13 on the substrate 8 (401) then the ruthenium layer 15 on the first soft underlayer 13 (402) followed by the second soft underlayer 14 on the ruthenium layer 15(403). The orientation control layer 17 is then formed on the second soft underlayer 14 (404) and the intermediate layer 18 is formed on the orientation control layer 17 (405). The first granular recording layer 20 is formed on the intermediate layer 18 (406) and the exchange layer is then formed on the first granular recording layer 20 (407). The second granular recording layer 21 is formed on the exchange layer 12 (408) and the upper recording layer 23 is formed on the second granular recording layer 21 (409). The formation of the protective layer 24 on the upper recording layer 23 follows (410), with the formation of the lubricant layer 25 (411) completing the formation of the perpendicular magnetic recording medium.

By optimization of:

(i) magnetic anisotropy of first and second granular magnetic layers 20, 21;
(ii) saturation magnetization ratio (M1/M2>1), and
(iii) the exchange layer, the perpendicular recording medium may have an improved thermal decay (dHc/dT, dHn/dT), and a higher signal to noise ratio.

Whilst the foregoing description has described exemplary embodiments, it will be understood by those skilled in the technology concerned that many variations in details of design, construction and/or operation may be made without departing from the present invention.

1. A perpendicular magnetic recording medium on a substrate, the perpendicular magnetic recording medium comprising a recording layer; the recording layer comprising a first granular recording layer and a second granular recording layer, the ratio of saturation magnetization of the first granular recording layer and the second granular recording layer being greater than 1.

2. A perpendicular magnetic recording medium on a substrate, the perpendicular magnetic recording medium comprising a recording layer; the recording layer to comprising a first granular recording layer and a second granular recording layer, the first granular recording layer having a relatively high magnetic anisotropy compared to the second granular recording layer magnetic anisotropy.

3. A perpendicular magnetic recording medium as claimed in claim 2, wherein the ratio of saturation magnetization of the first granular recording layer and the second granular recording layer is greater than 1.

4. A perpendicular magnetic recording medium as claimed in claim 1, wherein the first granular recording layer has a relatively high magnetic anisotropy compared to the second granular recording layer magnetic anisotropy.

5. A perpendicular magnetic recording medium as claimed in claim 1 further comprising an exchange layer between the first granular recording layer and the second granular recording layer.

6. A perpendicular magnetic recording medium as claimed in claim 5, wherein the exchange layer comprises CoCr with the Cr content being the range of 20 to 60 at %.

7. A perpendicular magnetic recording medium as claimed in claim 6, wherein the exchange layer further comprises at least one additive selected from the group consisting of: TiO₂, Cr₂O₃, SiO₂, ZrO₂, B₂O₃, Nb₂O₅, MgO, Al₂O₃, Ta₂O₅, HfO₂, Y₂O₂, V₂O₅ and WO₃; the at least one additive being in the range 0 to 20 at %.

8. A perpendicular magnetic recording medium as claimed in claim 5, wherein the exchange layer has a thickness in the range 0 to 10 A.

9. A perpendicular magnetic recording medium as claimed in claim 1 further comprising a soft underlayer on the substrate, and an isolation layer on the soft underlayer, the recording layer being on the isolation layer.

10. A perpendicular magnetic recording medium as claimed in claim 1 further comprising an upper recording layer on the second granular recording layer.

11. A method for forming a perpendicular magnetic recording medium on a substrate, the method comprising forming a first granular recording layer, forming an exchange layer on the first granular recording layer, and forming a second granular recording layer on the exchange layer; the ratio of saturation magnetization of the first granular recording layer and the second granular recording layer being greater than 1.

12. A method as claimed in claim 11, wherein before the first granular recording layer is formed, a soft underlayer is formed on the substrate and an isolation layer is formed on the soft underlayer, the first granular recording layer being formed on the isolation layer.

13. A method as claimed in claim 12, wherein forming the soft underlayer comprises forming a first soft underlayer on the substrate, forming a layer of ruthenium on the first soft underlayer, and forming a second soft underlayer on the layer of ruthenium.

14. A method as claimed in claim 13, wherein forming the isolation layer comprises forming an orientation control layer on the second soft underlayer and forming an intermediate layer on the orientation control layer.

15. A method as claimed in claim 11 further comprising forming an upper recording layer on the second granular recording layer, forming a protective layer on the upper recording layer, and forming a lubricant layer on the protective layer.

16. A method as claimed in claim 11, wherein the first granular layer, the exchange layer and the second granular layer are formed by DC magnetron sputtering.
